(19) United States
(12) Patent Application Publication
(10) Pub. No.: US 2012/0025315 A1
(43) Pub. Date: Feb. 2, 2012

(54) Transistor with Embedded Strain-Inducing Material and Dummy Gate Electrodes Positioned Adjacent to the Active Region

(75) Inventors: Stephan Kronholz, Dresden (DE); Gunda Beernink, Dresden (DE); Maciej Wiatr, Dresden (DE)

(73) Assignee: GLOBALFOUNDRIES INC., Grand Cayman (KY)

(21) Appl. No.: 13/154,941

(22) Filed: Jun. 7, 2011

(30) Foreign Application Priority Data
Jul. 30, 2010 (DE) 10 2010 038 743.6

(51) Int. Cl. H01L 29/78; H01L 21/336

(52) U.S. Cl. 257/365; 438/283; 257/E29.264; 257/E21.409

(57) ABSTRACT

The uniformity of transistor characteristics may be enhanced for transistors having incorporated therein a strain-inducing semiconductor material by using appropriately positioned dummy gate electrode structures. To this end, the dummy gate electrode structures may be positioned such that these structures may connect to or may overlap with the edge of the active region, thereby preserving a portion of the initial semiconductor material of the active region at the edge thereof upon forming the corresponding cavities.

### BACKGROUND OF THE INVENTION

1. Field of the Invention

Generally, the present disclosure relates to the fabrication of integrated circuits, and, more particularly, to transistors having strained channel regions by using embedded silicon/germanium (Si/Ge) and the like so as to enhance charge carrier mobility in the channel regions of the transistors.

2. Description of the Related Art

The fabrication of complex integrated circuits requires the provision of a large number of transistor elements, which represent the dominant circuit element for complex circuits. For example, several hundred millions of transistors may be provided in presently available complex integrated circuits. Generally, a plurality of process technologies are currently practiced, wherein, for complex circuitry, such as microprocessors, storage chips and the like, CMOS technology is currently the most promising approach due to the superior characteristics in view of operating speed and/or power consumption and/or cost efficiency. In CMOS circuits, complementary transistors, i.e., P-channel transistors and N-channel transistors, are used for forming circuit elements, such as inverters and other logic gates to design highly complex circuit assemblies, such as CPUs, storage chips and the like. During the fabrication of complex integrated circuits using CMOS technology, transistors, i.e., N-channel transistors and P-channel transistors, are formed on a substrate including a crystalline semiconductor layer. A MOS transistor, or generally a field effect transistor, irrespective of whether an N-channel transistor or a P-channel transistor is considered, comprises so-called PN junctions that are formed by an interface of highly doped drain and source regions with an inversely or weakly doped channel region disposed between the drain region and the source region. The conductivity of the channel region, i.e., the drive current capability of the conductive channel, is controlled by a gate electrode formed in the vicinity of the channel region and separated therefrom by a thin insulating layer. The conductivity of the channel region, upon formation of a conductive channel due to the application of an appropriate control voltage to the gate electrode, depends on, among other things, the dopant concentration, the mobility of the charge carriers and, for a given extension of the channel region in the transistor width direction, on the distance between the source and drain regions, which is also referred to as channel length. Thus, the reduction of the channel length, and associated therewith the reduction of the channel resistivity, is a dominant design criterion for accomplishing an increase in the operating speed of the integrated circuits.

The continuing shrinkage of the transistor dimensions, however, involves a plurality of issues associated therewith that have to be addressed so as to not unduly offset the advantages obtained by steadily decreasing the channel length of MOS transistors. For example, highly sophisticated dopant profiles, in the vertical direction as well as in the lateral direction, are required in the drain and source regions so as to provide low sheet and contact resistivity in combination with desired channel controllability. Moreover, the gate dielectric material may also be adapted to the reduced channel length in order to maintain the required channel controllability. However, some mechanisms for maintaining high channel controllability may also have a negative influence on the charge carrier mobility in the channel region of the transistor, thereby partially offsetting the advantages gained by the reduction of the channel length.

Since the continuous size reduction of the critical dimensions, i.e., the gate length of the transistors, necessitates the adaptation and possibly the new development of highly complex process techniques and may also contribute to less pronounced performance gain due to mobility degradation, it has been proposed to enhance the channel conductivity of the transistor elements by increasing the charge carrier mobility in the channel region for a given channel length, thereby enabling a performance improvement that is comparable with the advance to a technology standard that would require extremely scaled critical dimensions, while avoiding or at least postponing many of the process adaptations associated with device scaling.

One efficient mechanism for increasing the charge carrier mobility is the modification of the lattice structure in the channel region, for instance by creating tensile or compressive stress in the vicinity of the channel region so as to produce a corresponding strain in the channel region, which results in a modified mobility for electrons and holes, respectively. For example, creating tensile strain in the channel region for a standard crystallographic configuration of the active silicon material, i.e., a (100) surface orientation with the channel length aligned to the <110> direction, increases the mobility of electrons, which in turn may directly translate into a corresponding increase in conductivity. On the other hand, compressive strain in the channel region may increase the mobility of holes, thereby providing the potential for enhancing the performance of P-type transistors. The introduction of stress or strain engineering into integrated circuit fabrication is an extremely promising approach, since strained silicon may be considered as a “new” type of semiconductor material, which may enable the fabrication of fast powerful semiconductor devices without requiring expensive semiconductor materials, while many of the well-established manufacturing techniques may still be used.

Consequently, it has been proposed to introduce, for instance, a silicon/germanium material next to the channel region so as to induce a compressive stress that may result in a corresponding strain. When forming the silicon/germanium material, the drain and source regions of the PMOS transistors are selectively recessed to form cavities, while the NMOS transistors are masked, and subsequently the silicon/germanium material is selectively formed in the cavities of the PMOS transistor by epitaxial growth.

Although the technique has significant advantages in view of performance gain of P-channel transistors and thus of the entire CMOS device, it turns out, however, that, in advanced semiconductor devices including a large number of transistor elements, an increased variability of device performance may be observed, which may be associated with the above-described technique for incorporating a strained silicon/germanium alloy in the drain and source regions of P-channel transistors.

The presence of a strain-inducing silicon/germanium material in the drain and source regions of P-channel transistors may drastically alter the current drive capability of the transistor and, thus, even small variations during the incorporation of the silicon/germanium material or any variations of the material composition may, therefore, significantly affect performance of the P-channel transistors. The strain-inducing effect of the embedded silicon/germanium material depends on the amount of the embedded strain-inducing semiconductor material, the distance with respect to the channel region and also depends on the size and shape of the strain-inducing semiconductor material. For example, incorporating an increased fraction of germanium may result in an increase of the resulting strain, since the corresponding lattice mismatch between the silicon/germanium material and the silicon material of the active region may be increased. The maximum concentration of germanium in the semiconductor alloy, however, may depend on the process strategy used, since further increasing the germanium concentration may result in undue germanium agglomeration, which in turn may provide increased lattice defects and the like. Furthermore, the amount of the strain-inducing material and the shape thereof in the drain and source regions may depend on the size and shape of the cavities formed in the drain and source areas, wherein also the effective distance from the channel region may be substantially determined on the basis of the size and shape of the corresponding cavities.

A typical conventional process flow for forming an embedded silicon/germanium material in P-channel transistors may include the following process steps. After forming the active semiconductor regions, which is typically accomplished by forming appropriate isolation regions that laterally delineate the active regions, the electrode structures are formed on the basis of any appropriate process strategy. That is, appropriate materials, such as dielectric materials, electrode materials and the like, are provided in combination with one or more appropriate dielectric cap materials which may be used, in addition to its use in the actual patterning of the gate layer stack, as an etch and deposition mask in a later manufacturing stage when the embedded strain-inducing silicon/germanium material is deposited. In sophisticated applications, the gate electrode structures of field effect transistors are provided with a gate length of 50 nm and less, thereby providing superior transistor performance, for instance in terms of switching speed and drive current capability. The reduced critical dimensions, however, may also contribute to a pronounced dependency of the resulting transistor performance on process variations, in particular when any such process variations may occur upon implementing a very efficient performance enhancing mechanism, such as embedding the strain-inducing silicon/germanium material in P-channel transistors. For example, a variation of the lateral distance of the silicon/germanium material with respect to the channel region may over-proportionally influence the finally obtained performance, in particular when basically extremely scaled transistors are considered. For example, forming any sidewall spacers on the gate electrode structures for preserving integrity of sensitive materials, such as the gate dielectric material, the electrode material and the like, may have a significant influence on the lateral distance. Merely reducing the resulting spacer width may not be compatible with other device requirements, such as integrity of the gate material. Consequently, in particular upon further reducing the gate length, even a minute variation of the spacer width may significantly contribute to overall variability of the resulting performance gain obtained by the embedded silicon/germanium material.

Based on the dielectric cap material and the sidewall spacer structure, cavities may then be etched into the drain and source areas, wherein the size and shape may be substantially determined on the basis of the etch parameters of the corresponding etch process. It should be appreciated that any other transistors, such as N-channel transistors, in which the incorporation of a silicon/germanium material is not required are covered by an appropriate mask layer. After any appropriate cleaning processes for preparing exposed surface areas of the silicon material in the drain and source areas, a selective epitaxial growth process may be performed, in which the silicon/germanium material may be selectively deposited on exposed silicon surface areas, while a significant deposition of the semiconductor material on dielectric surface areas, such as dielectric cap materials, sidewall spacers, isolation regions and mask layers, may be suppressed.

As discussed above, the final gain in performance of the P-channel transistors may depend critically on the amount of strained semiconductor material and its offset from the channel region. Consequently, great efforts have been made in developing a process strategy in which a plurality of complex processes may be performed on the basis of a high degree of process uniformity across the individual semiconductor die regions and also across entire substrates to reduce any variability of the transistor characteristics.

It is well known that a plurality of processes, such as plasma assisted etch processes, deposition processes and the like, may be influenced by the local configuration of the substrate surface to be treated. That is, the etch rate in plasma assisted etch processes may be influenced by the “pattern” density, i.e., by the ratio of surface area to be etched with respect to the surface area of substantially etch-resistive materials. For example, when a large number of densely packed active areas may have to be provided with corresponding cavities, the resulting etch rate in this device area may differ from an etch rate in an area in which a moderate number of more or less isolated active regions may have to be etched. The corresponding effect is also known as “pattern loading.” Similarly, the deposition rate may vary to a certain degree depending on the local pattern density, wherein, for instance, in selective epitaxial growth recipes for forming silicon/germanium, an increased fill behavior in densely packed device areas may be observed compared to more or less isolated device regions, while in other cases the opposite deposition behavior may occur.

As previously discussed, a corresponding pattern-sensitive etch and deposition behavior may, however, significantly influence the resulting transistor characteristics upon forming an embedded silicon/germanium material. Consequently, great efforts have been made in the past in order to provide very uniform process conditions across single die regions and across the entire substrates, as will be described in more detail with reference to FIGS. 1a-1e.

FIG. 1a schematically illustrates a top view of a semiconductor device 100 in which a die region 150 may be illustrated in a schematic manner. A die region is to be understood as a portion of a semiconductor material in and above which one or more circuit portions may be implemented, which may represent a functional unit and which may be packaged as a semiconductor chip into an appropriate package substrate in a later manufacturing stage. As illustrated, the die region 150 may comprise a first device area 150A, which may be understood as a “densely packed” device area, while a second device area 150B may be considered as a non-dense device area. For example, the densely packed device area 150A may comprise a plurality of closely spaced transistor elements 140, wherein also a significant number of P-channel transistors may have to be implemented, for instance in a static RAM area of the device 100. On the other hand, in the device area 150B, the number of transistors 140 per unit area may be less compared to the area 150A.

FIG. 1b schematically illustrates a cross-sectional view of the semiconductor device 100 in a region in which one or more of the transistor elements 140 are provided. As illustrated, the device 100 comprises a substrate 101, above which is formed a semiconductor layer 102, such as a silicon layer and the like. The substrate 101 and the semiconductor layer 102 may form a silicon-on-insulator (SOI) configuration when a buried insulating material (not shown) is formed below the semiconductor layer 102 so as to vertically isolate the semiconductor layer 102. In other cases, the semiconductor layer 102 represents a part of a crystalline material of the substrate 101, thereby forming a bulk configuration. In the manufacturing stage shown, the semiconductor layer 102 may actually be comprised of a plurality of semiconductor regions or active regions, which are typically laterally delineated by appropriate isolation regions. For convenience, in FIG. 1b, a single active region 102A is illustrated, which is surrounded by an isolation region 102C. It should be understood that an active region is to be understood as being a semiconductor region of the layer 102, in and above which at least one transistor element is to be provided. As shown in FIG. 1b, a plurality of the transistors 140 may be formed in and above the active region 102A, as may be required in densely packed device areas, such as the device area 150A (FIG. 1a). It should further be appreciated that the transistors 140 may also be provided in the device area 150B (FIG. 1a), however with a reduced “density,” that is, the number of active regions may be significantly less compared to the region 150A, as discussed above. In the manufacturing stage shown, the transistors 140 may comprise gate electrode structures 130A, 130B, which may have basically the same configuration. For example, the gate electrode structures 130A, 130B comprise a gate dielectric material 132 and an electrode material 131, wherein these materials may have any appropriate configuration. For example, the gate dielectric material 132 may comprise a silicon oxide-based material, while, in some sophisticated applications, in addition to or alternatively, a high-k dielectric material may be incorporated in the gate dielectric material 132. A high-k dielectric material is to be understood as a dielectric material having a dielectric constant of 10.0 or greater. Similarly, the electrode material 131 may comprise a semiconductor material, such as polysilicon and the like, possibly in combination with a metal-containing electrode material, which may typically be provided in combination with a high-k dielectric material. Furthermore, the gate electrode structures 130A, 130B typically comprise a dielectric cap layer 134 and a sidewall spacer structure 133 in order to appropriately confine the sensitive materials 132 and 131. In sophisticated semiconductor devices, the gate electrode structures 130A, 130B may be provided with a gate length, i.e., in FIG. 1b the horizontal extension of the electrode material 131, of approximately 50 nm and less. Furthermore, the semiconductor device 100 comprises a “gate electrode” structure 130D that is positioned above and adjacent to the active region 102A and may be considered as a dummy structure in order to provide superior process conditions during the further processing of the device 100. The dummy gate electrode structure 130D may have the same configuration as the functional gate electrode structures 130A, 130B.

The semiconductor device 100 as illustrated in FIG. 1b may be formed on the basis of the following process techniques. The lateral size and shape of the active region 102A is defined upon forming the isolation structure 102C. To this end, an appropriate lithography process is applied in which the pattern of the device is transferred into an etch mask, which may be provided in the form of a resist material in combination with an appropriate hard mask material, such as silicon dioxide, silicon nitride and the like. Thereafter, a trench is etched into the semiconductor layer 102, thereby defining essentially the shape of the isolation structure 102C and thus of the active region 102A. That is, for instance based on the etch recipe applied, the corresponding sidewalls 102S of the isolation structures 102C may have a more or less inclined configuration, depending on the etch strategy used. Generally, the lateral size of the active region 102A is selected so as to obtain the transistors 140 with a desired transistor width, i.e., the extension of the active region 102A in a direction perpendicular to the drawing plane of FIG. 1b, and also to provide the gate electrode structures 130A, 130B with a desired pitch in accordance with overall design requirements. For example, in densely packed device areas, the gate electrode structures 130A, 130B may have to be positioned with a minimum critical pitch, i.e., with a minimum pitch that is compatible with the manufacturing techniques and the resulting transistor characteristics. For example, the critical minimum pitch may be of a similar order of magnitude as the gate length, for instance two or three times the gate length of the gate electrode structures 130A, 130B. Thereafter, the isolation trenches are refilled with an appropriate dielectric material, such as silicon dioxide, and the further processing is continued by removing any excess material, thereby providing a substantially planar surface topography. Prior to or after the formation of the isolation region 102C, appropriate implantation processes are typically applied in combination with associated masking regimes in order to incorporate a desired well dopant species into the various active regions, thereby defining the basic transistor characteristics. For example, dopant species may be incorporated into the active region 102A in order to define the basic characteristics. Next, the gate electrode structures 130A, 130B in combination with the dummy structure 130D are formed by using well-established process techniques, wherein, as discussed above, depending on the configuration of the gate electrode structures 130A, 130B, additional process steps may have to be implemented, for instance providing appropriate high-k dielectric materials in combination with metal-containing cap materials and the like. Thereafter, a sophisticated lithography and etch process is applied in order to pattern the electrode material 131 and the cap layer 134, possibly on the basis of hard mask materials and the like, followed by the deposition of one or more material layers which may then be etched into the spacer elements 133, at least above the active region 102A, in order to obtain the spacer structure 133. In other device areas, the corresponding spacer layers may be preserved so as to act as an etch and/or deposition mask during the further processing, as is also described above. The spacer structure 133 may substantially determine the lateral offset of corresponding cavities 103 to be formed in the active region 102A in order to incorporate a strain-inducing semiconductor material. Consequently, upon further reducing the overall dimensions in the device 100, for instance by applying technologies associated with the 45 nm technology node, superior process uniformity is required upon depositing materials and etching the same due to the subtle pattern loading effects described above. To this end, the dummy structure 130D may be provided, which may result in similar process conditions as may also be encountered by the gate electrode structures 130A, 130B, for instance when forming the spacer structure 133. It should be appreciated that a plurality of closely spaced dummy structures 130D may be provided if considered appropriate for “simulating” the process conditions of a densely packed device area. Consequently, upon performing an etch process or a sequence of etch processes for etching into the active region 102A, very similar process conditions may be established, for instance in terms of ion concentration, ion bombardment and the like. Hence, the cavities 103 may be formed with a similar shape and with a moderately high uniformity with respect to its depth.

FIG. 1c schematically illustrates the device 100 in a further advanced manufacturing stage. As shown, a strain-inducing silicon/germanium alloy 141 is provided in the cavities 103 (FIG. 1b), which is accomplished on the basis of well-established selective epitaxial growth techniques. As discussed above, the deposition behavior of selective deposition processes may strongly depend on the type of precursor material used and the process conditions. Moreover, the deposition may be substantially restricted to exposed silicon surface areas, while any dielectric surface areas may not provide appropriate surface conditions so as to cause the adherence of the strain-inducing semiconductor material. As discussed above, some deposition recipes may tend to grow an increased amount of material in densely packed device areas, while other selective deposition recipes may result in the opposite fill behavior. By providing the dummy structures 130D, however, a substantially balanced deposition behavior may be obtained for semiconductor devices including sophisticated P-channel transistors formed according to the 45 nm technology node.

FIG. 1c schematically illustrates the device for a substantially vertical sidewall 102S of the isolation region 102C.

FIG. 1d schematically illustrates the fill conditions for an inclined sidewall 102S. For example, a corresponding reduction of the fill height may be observed at the edge region of the active region 102A.

As discussed above, a significant gain in performance of the P-channel transistors 140 may be accomplished by incorporating the strain-inducing semiconductor material 141, wherein, however, also a high degree of uniformity may be required across the entire device, since any non-uniformities upon incorporating the material 141 may result in a significant variability of the resulting threshold voltage, which may not be compatible with the requirement of appropriately qualifying the resulting semiconductor devices 100. For this reason, appropriate test structures have been implemented into the device 100 in order to precisely monitor the uniformity of the P-channel transistors 140.

FIG. 1e schematically illustrates a top view of a corresponding test structure 160, which may comprise a plurality of gate electrode structures having the same configuration as the gate electrode structures 130A, 130B that may be formed above an active region, such as the region 102A. Furthermore, laterally adjacent to the active region 102A, the dummy gate electrode structures 130D may be provided. With respect to forming the test structure 160, the same process techniques may be used as described above with reference to the transistors 140. Consequently, based on the structure 160, transistor characteristics, such as the gate voltage required for inducing saturation current of the various transistors, may be determined for any of the transistor configurations in the test structure 160. For example, the corresponding transistor characteristics may be determined for edge transistors and central transistors, wherein the test structure 160 may be positioned in densely packed device regions and in non-dense device regions, such as the regions 150A, 150B of FIG. 1a. Consequently, based on the measurement results obtained from the test structure, the process techniques described above have been determined to provide the desired high degree of uniformity in combination with dummy structures 130D for transistors corresponding to the 45 nm technology. It turns out, however, that, upon further reducing the critical dimensions of the transistors and thus of the gate electrode structures, a significant variation of, for instance, the threshold voltage may be observed, which may not be compatible with requirements for appropriately qualifying semiconductor devices.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present disclosure provides manufacturing techniques and semiconductor devices in which superior uniformity may be achieved, in particular during the critical deposition of a strain-inducing semiconductor alloy, even for highly scaled transistor devices having a gate length of approximately 40 nm and less, by appropriately positioning the dummy gate electrode structures with respect to the edge region of active transistor regions. Without intending to restrict the present application to the following explanation, it is nevertheless believed that generally the provision of dummy gate electrode structures adjacent to actual gate electrode structures may significantly enhance the overall process uniformity, wherein, however, the difference in deposition behavior of the sidewalls formed between the isolation structure and an active region may result in a certain degree of non-uniformity in transistor characteristics when increasingly complex manufacturing processes and reduced gate length dimensions have to be implemented. For this reason, in the present disclosure, an appropriate geometry may be applied in which a dummy gate electrode structure or a regular gate electrode structure may be positioned so as to at least connect to the edge of the active region, while, in other cases, the dummy gate electrode structure or additional gate electrode structure may be formed on a portion of the edge region so that, upon forming cavities in the active region, material of the initial active region may be preserved at the sidewall of the insulation region, thereby providing superior process conditions during the subsequent selective epitaxial growth process. That is, by preserving a portion of the initial semiconductor material at the edge region, very similar conditions in terms of material composition and cavity geometry may be provided at the side of the isolation structure and the side of the actual gate electrode structure. Consequently, upon generally reducing the overall transistor dimensions, an increasing influence of any non-uniformities upon providing the strain-inducing semiconductor material may be significantly reduced, thereby contributing to superior uniformity of the resulting transistor characteristics, irrespective of the actual design of the semiconductor device under consideration. That is, the concept of providing similar device topography at the edge of active regions and the center thereof may be accomplished by means of dummy gate electrode structures or actual gate electrode structures, wherein the basic geometry of the isolation regions may be appropriately modified so as to allow the positioning of the electrode structure at the edge so as to result in a residual semiconductor material upon forming the cavities. For example, a sidewall spacer structure, which may typically be provided for ensuring integrity of sensitive gate materials, may be positioned such that at least the spacer structure may connect to the edge of the active region, thereby providing the desired material residue upon forming the cavities.

One illustrative method disclosed herein comprises forming a gate electrode structure of a transistor above an active region that is laterally delineated by an isolation region. The method further comprises forming a dummy gate electrode structure above the isolation region so as to at least connect to an edge portion of the active region, wherein the gate electrode structure and the dummy gate electrode structure are oriented in parallel to each other. The method further comprises forming a strain-inducing semiconductor alloy in the active region in the presence of the gate electrode structure and the dummy gate electrode structure. Additionally, the method comprises forming drain and source regions of the transistor in the active region.

A further illustrative method disclosed herein relates to forming a transistor in a semiconductor device. The method comprises forming a first gate electrode structure above an active region that is laterally delineated by an isolation region. Additionally, the method comprises forming a second gate electrode structure substantially parallel with the first gate electrode structure above the isolation region so as to connect to an edge region of the active region. Moreover, the method comprises forming cavities in the active region in the presence of the first and second gate electrode structures. Additionally, a strain-inducing semiconductor alloy is formed in the cavities and drain and source regions are formed in the active region.

One illustrative semiconductor device disclosed herein comprises a first gate electrode structure formed above an active region that is laterally delineated by an isolation region. The semiconductor device further comprises a second electrode structure formed above the isolation region and connecting to an edge area of the active region, wherein the first and second electrode structures are oriented substantially in parallel to each other. The semiconductor device further comprises a strain-inducing semiconductor alloy formed in the active region, wherein the strain-inducing semiconductor alloy laterally connects to the edge area.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a top view of a semiconductor device including a densely packed device region and a non-dense device region;

FIGS. 1b-1d schematically illustrate cross-sectional views of the semiconductor device in which dummy gate electrode structures may be used for enhancing uniformity during the formation of a strain-inducing silicon/germanium alloy, according to conventional strategies;

FIG. 1e schematically illustrates a top view of a test structure for determining the uniformity of transistor characteristics;

FIGS. 2a and 2b schematically illustrate top views of a semiconductor device wherein active regions of different size may be provided together with gate electrode structures of transistors and with electrode structures positioned adjacent to the active region so as to connect to the edge thereof or overlapping with the active region, according to illustrative embodiments;

FIGS. 2c and 2d schematically illustrate cross-sectional views of the semiconductor device with a plurality of gate electrode structures formed above an active region and with at least one dummy gate electrode structure or any other type of electrode structures positioned so as to provide superior deposition conditions upon forming a strain-inducing semiconductor alloy, according to illustrative embodiments;

FIG. 2e schematically illustrates a cross-sectional view of the semiconductor device in a further advanced manufacturing stage; and

FIGS. 2f and 2g schematically illustrate cross-sectional views of the semiconductor device wherein a single transistor may be provided in and above an active region together with an adjacent electrode structure in further advanced manufacturing stages, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally provides manufacturing techniques and semiconductor devices in which a superior uniformity of transistor characteristics may be obtained in transistors in which an embedded strain-inducing semiconductor material is to be provided on the basis of a selective epitaxial growth process, for instance, in the form of a silicon/germanium alloy, a silicon/carbon alloy and the like. The superior uniformity may be achieved by appropriately configuring the isolation region and active region of one or more transistors such that an electrode structure, such as a dummy gate electrode structure or a regular gate electrode structure that is to be provided electrically insulated from the active region, provides superior uniformity during the entire patterning process for forming the gate electrode structures and during the etch process for forming cavities in the active region. Furthermore, the electrode structure may be positioned such that, upon forming the cavities, material of the initial semiconductor region may be preserved at the edge of the active region, thereby also providing superior process uniformity during the subsequent selective epitaxial growth process. To this end, the gate electrode structure may be formed so as to connect to the edge of the active region in a manufacturing stage immediately prior to forming the corresponding cavities, while in other cases a certain degree of overlap may be provided, for instance by means of the corresponding sidewall spacer structure of the electrode structure. In this manner, the device geometry and the material composition at the edge under consideration and at the center of the active region may be substantially identical, thereby resulting in superior deposition uniformity. The appropriate positioning of the electrode structure, which may act as a dummy structure, may be accomplished by appropriately selecting the geometric layout of the isolation region and the active region for a given lateral distance between the actual gate electrode structure or structures to be formed above the active region and the dummy gate electrode structure. For example, the length of the active region may be appropriately selected for a given pitch of electrode structures, thereby obtaining the desired connection to the edge of the active region without significantly influencing the overall characteristics of the one or more transistors to be formed in and above the active region under consideration.

Consequently, even extremely complex transistors, for instance requiring the incorporation of sophisticated material systems, such as high-k dielectric materials, metal-containing electrode materials and the like, may be provided with superior uniformity, even if a gate length of approximately 40 nm and less may have to be implemented. It should be appreciated that the principles disclosed herein may be advantageously applied to P-channel transistors when incorporating a silicon/germanium material on the basis of well-established selective epitaxial growth techniques since, as discussed above, superior uniformity of the strain conditions may be achieved, which may also directly translate into reduced variability of transistor characteristics, such as threshold voltage and the like. In other cases, the principles may be applied to any other strain-inducing semiconductor materials such as silicon/carbon, silicon/tin, silicon/germanium/tin and the like, which may be provided on the basis of selective epitaxial growth techniques.

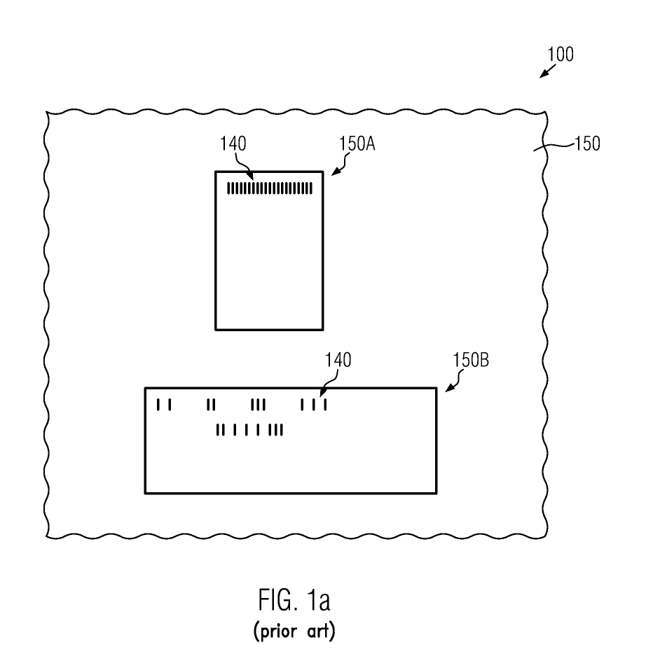

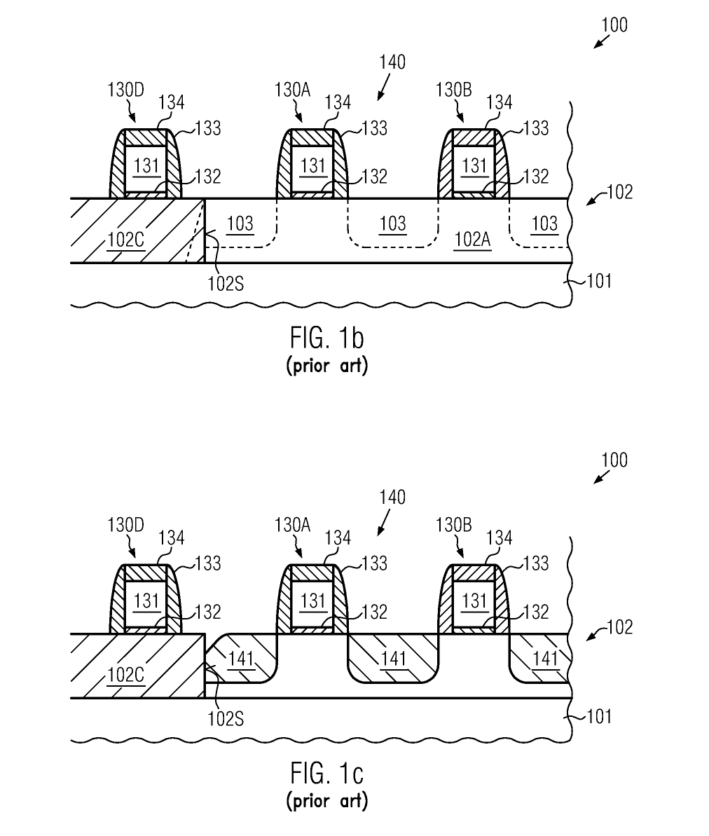

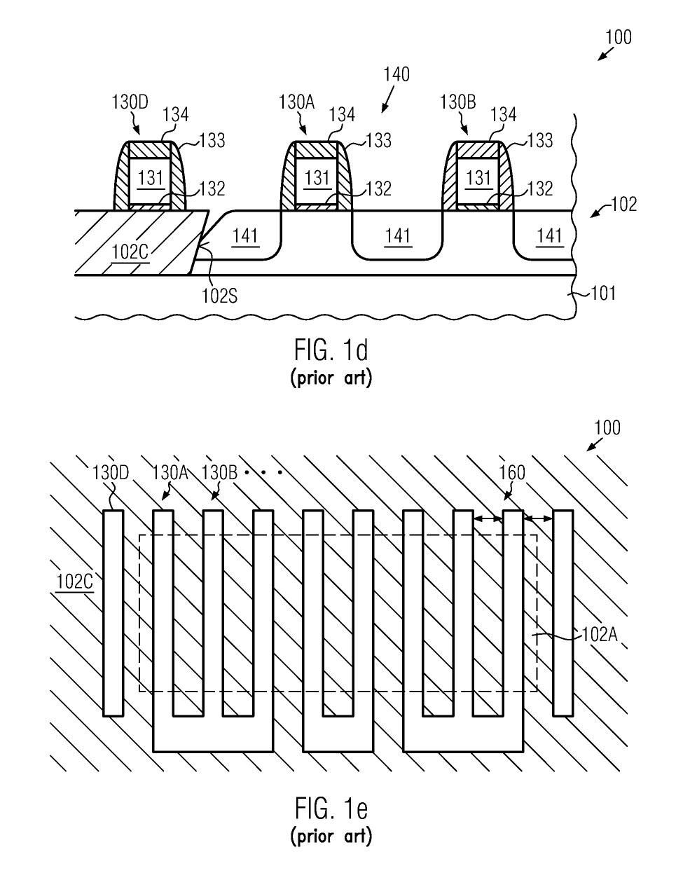

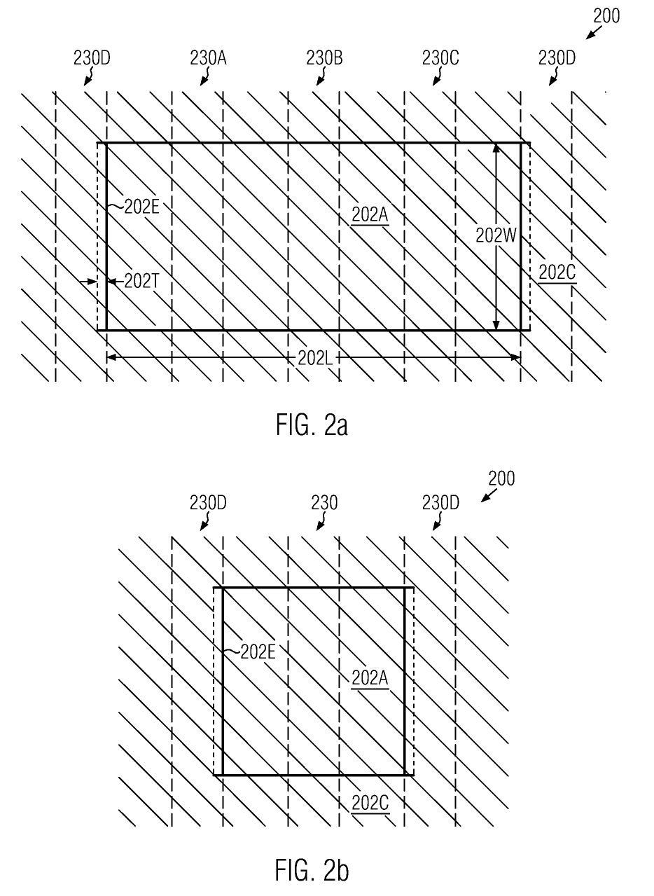

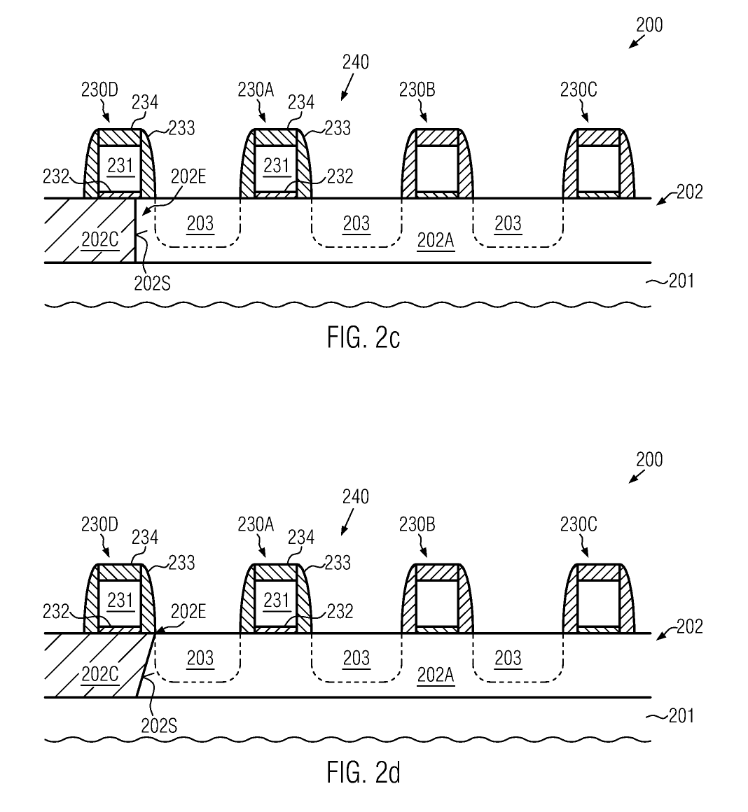

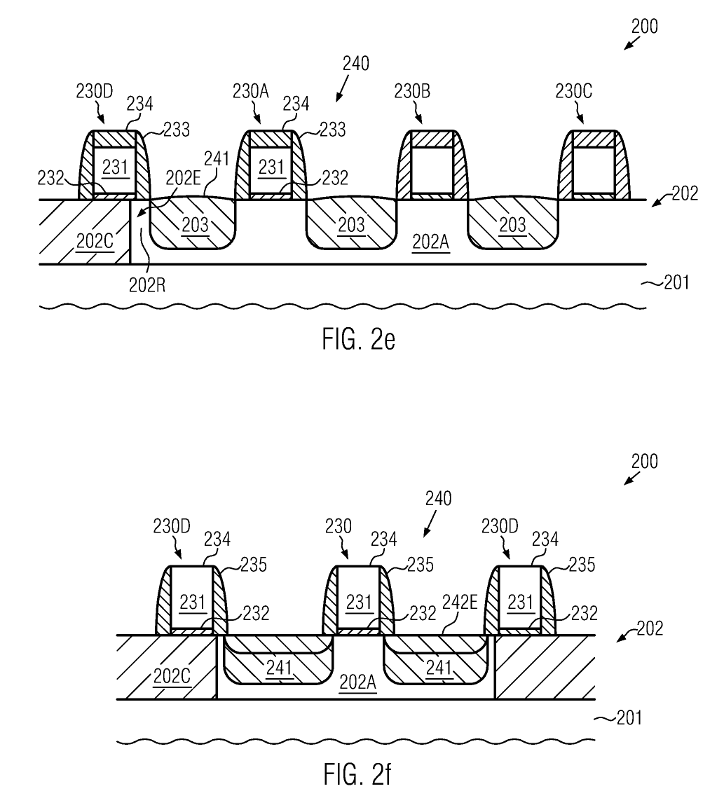

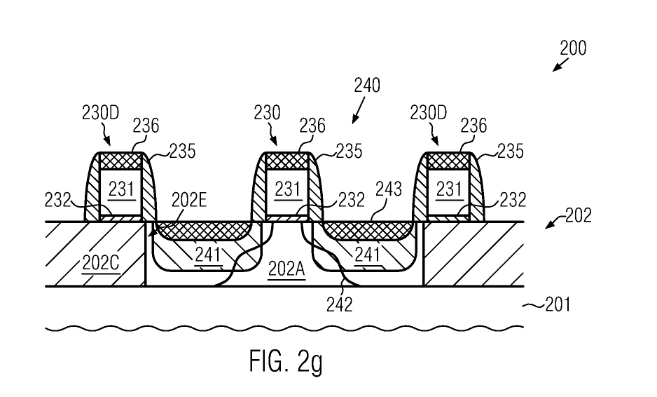

With reference to FIGS. 2a-2g, further illustrative embodiments will now be described in more detail, wherein reference also may be made to FIGS. 1a-1e, if appropriate.

FIG. 2a schematically illustrates a top view of a semiconductor device 200 in an early manufacturing stage. As shown, the device 200 may comprise an active region 202A, which may represent a portion of a semiconductor layer, as will be described later on in more detail with reference to FIG. 2c, and which may be laterally delineated by an isolation region 202C, for instance in the form of a shallow trench isolation and the like. The active region 202A may have a length 202L and a width 202W in accordance with design requirements in order to provide a desired transistor width and to accommodate a desired number of transistors to be formed in and above the active region 202A. In the embodiment shown, three transistors may have to be provided in and above the active region 202A, wherein, for convenience, gate electrode structures 230A, 230B, 230C are indicated as dashed lines. Furthermore, as previously discussed, one or more electrode structures 230D may be provided which, however, may be electrically insulated from the active region 202A and may represent, in some illustrative embodiments, dummy gate electrode structures, that is, electrically non-functional electrode structures, while in other cases the one or more electrode structures 230D may represent any conductive lines or portions of gate electrode structures which may be used in other transistors (not shown) or which may be used for providing electrical connection between certain circuit components. Consequently, the electrode structures 230D may act as “dummy structures” during any deposition and etch processes with respect to the “actual” gate electrode structures 230A, 230B and 230C in order to provide similar process conditions, in particular at an edge 202E of the active region 202A. Contrary to any conventional strategies, as are for instance described above with reference to the semiconductor device 100, the electrode structures 230D may be positioned such that, at least in a manufacturing stage for forming cavities in the active region 202A, the electrode structures 230D, such as a sidewall spacer structure formed thereon at this manufacturing stage, may connect to the edge 202E of the active region 202A. As, for example, shown by the solid line, in this case, the electrode structures 230D may be aligned to the edge 202E, for instance when the isolation region 202C may have an inclined sidewall, as will be described later on in more detail. In other cases, as indicated by the dashed line, the electrode structure 230D may overlap with the active region 202A and may thus be formed on the edge region 202E and may extend into the active region 202A to a certain degree, for instance by approximately one to several nanometers. To this end, for a given pitch of the electrode structures 230D, 230A, 230B, 230C, the length 202L of the active region 202A may be appropriately selected so as to obtain the desired degree of overlap, as indicated by 202T.

FIG. 2b schematically illustrates a top view of the semiconductor device 200 in embodiments in which the active region 202A is to receive a single transistor and thus a single gate electrode structure 230 may be formed above the active region 202A. Similarly, the electrode structures 230D may be provided so as to connect to the edge region 202E or overlap with the active region 202A, as discussed above with reference to FIG. 2a.

FIG. 2c schematically illustrates a cross-sectional view of the semiconductor device 200, for instance for a portion of the configuration as shown in FIG. 2a. As illustrated, the device 200 may comprise a substrate 201 and a semiconductor layer 202, which may form a bulk configuration or an SOI configuration, as is also discussed above with reference to the semiconductor device 100. Furthermore, the isolation region 202C may have a substantially vertical sidewall 202S at the edge region 202E. Furthermore, FIG. 2c may represent a manufacturing stage immediately prior to forming cavities 203 in the active region 202A in order to provide an embedded strain-inducing semiconductor material therein. In this manufacturing stage, the gate electrode structures 230A, 230B, 230C may be formed on the active region 202A and may have any appropriate configuration. For example, the gate electrode structures 230A, 230B, 230C may comprise a gate dielectric material 232 in combination with one or more electrode materials 231, wherein these components may be confined on the basis of a dielectric cap material 234 and a sidewall spacer structure 233, wherein at least some of these components may be removed from the gate electrode structures 230A, 230B, 230C in a later manufacturing stage, depending on the overall process strategy to be used. As discussed above, the gate dielectric material 232 may comprise a high-k dielectric material and the electrode material 231 may comprise one or more metal-containing components, such as titanium nitride, tantalum nitride, aluminum, lanthanum and the like. The sidewall spacer structure may be comprised of silicon nitride, silicon dioxide and the like, and the dielectric cap material 234 may be provided in the form of silicon nitride, silicon dioxide and the like. Furthermore, a length of the gate electrode structures 230A, 230B, 230C may be 40 nm and less in some illustrative embodiments. It should be appreciated, however, that the principles disclosed herein may also be applied in some embodiments including gate electrode structures having a gate length of more than 40 nm. Furthermore, the active region 202A may have incorporated therein any appropriate dopant species in order to define the basic conductivity of transistors 240 to be formed on the basis of the active region 202A and the gate electrode structures 230A, 230B, 230C.

Furthermore, the electrode structure 230D may be provided and may have basically the same configuration as the actual gate electrode structures 230A, 230B, 230C, thereby ensuring very similar process conditions upon forming the electrode structures and during the further processing of the device 200, as is also discussed above. Furthermore, as illustrated, the electrode structure 230D may be formed so as to at least connect to the material of the active region 202A at the edge 202E, wherein, in the embodiment shown, the structure 230D may overlap and may thus be formed on a portion of the active region 202A. In the embodiment shown, the overlap may be created by the sidewall spacer structure 233 and a portion of the electrode material 231, while in other cases the spacer structure 233 may overlap while the electrode material 231 may be positioned above the isolation region 202C. A corresponding strategy may depend on the width of the spacer structure 233, which may be approximately 10 nm and significantly less in sophisticated applications.

The device 200 as shown in FIGS. 2a-2c may be formed on the basis of any appropriate process strategy when forming the electrode structures 230A, 230B, 230C, 230D, as is, for instance, also described above with reference to the semiconductor device 100. Contrary to conventional strategies, however, the active region 202A may be appropriately dimensioned so as to obtain the connection to the structure 230D or to obtain a desired degree of overlap, which may be accomplished by using an appropriately designed lithography mask or by appropriately adjusting the exposure conditions upon forming a resist material above the semiconductor layer 202 in an initial manufacturing stage, when a corresponding increase of the lateral dimensions of the active region 202A in the transistor width direction (FIG. 2a) may be tolerable. Consequently, by appropriately adapting the size of the active region 202A, and thus of the isolation region 202C, a desired certain pitch between the electrode structures 230A, 230B, 230C, 230D may be preserved, thereby obtaining very similar process conditions even at the edge 202E of the active region 202A. In other cases, when the pitch between the gate electrode structures 230A, 230B and 230C may not represent the minimum pitch for the technology under consideration, a device design may be used in which the pitch between the structure 230D and 230A in FIG. 2c may be selected so as to obtain a desired degree of overlap or connection to the active region 202A without changing the overall lateral dimensions of the active region 202A with respect to a basic layout. It should be appreciated that forming the active region 202A and the isolation region 202C so as to provide for a certain degree of overlap may thus result in superior process robustness with respect to any minute misalignments upon forming the electrode structures 230A, 230B, 230C, 230D.

FIG. 2d schematically illustrates the semiconductor device 200 according to illustrative embodiments in which the isolation region 202C may have an inclined sidewall surface 202S, wherein the electrode structure 230D may be positioned so as to connect to the active region 202A, i.e., to the edge 202E thereof. In this case, the electrode structure 230D may also “overlap” with a portion of the active region 202A with increasing depth when starting from a surface of the active region 202A. Consequently, also in this case, a certain amount of material of the active region 202A may be preserved along the depth direction upon forming corresponding cavities 203 if these cavities may have substantially vertical sidewalls. As previously discussed, the inclination of the sidewalls 202S of the isolation region 202C may depend on process characteristics, such as the specifics of plasma assisted etch recipes and the like.

In the manufacturing stage shown in FIGS. 2c and 2d, any appropriate etch strategy may be applied so as to form the cavities 203 in the active region 202A, while the spacer structure 233 and the dielectric cap layer 234 may act as efficient etch stop materials. Consequently, upon forming the cavities 203, a portion of the initial semiconductor material of the region 202A may be preserved at the edge 202E, for instance caused by a certain degree of overlap, as shown in FIG. 2c, or caused by the connection of the structure 230D to the edge 202E and the inclined sidewall surface 202S of the isolation region 202C.

FIG. 2e schematically illustrates the semiconductor device 200 in a further advanced manufacturing stage. As illustrated, after forming the cavities 203, a selective epitaxial growth process may be performed in order to form a strain-inducing semiconductor material 241 in the cavities 203. As previously explained, the selective deposition may be substantially restricted to exposed surface areas of the initial material of the active region 202A, wherein the specific positioning of the electrode structure 230D may preserve residual material 202R at the edge 202E, so that also the deposition process “sees” very similar process conditions at the gate electrode structure 230A and at the edge 202E, thereby providing substantially identical deposition conditions in these areas, which may thus result in superior uniformity of the material 241. Furthermore, the material 241 provided at the edge 202E may have a similar configuration as any material 241 provided in a central area of the active region 202A, for instance between the gate electrode structures 230A, 230B, thereby also providing superior uniformity of the corresponding transistors 240. Consequently, the corresponding strain conditions established in the active region 202A on the basis of the material 241 may have superior uniformity, thereby resulting in reduced variability of transistor characteristics, such as fluctuations in threshold voltage and the like. For example, the transistors 240 may be provided in the form of P-channel transistors with a silicon/germanium material, a silicon/tin material, a silicon/germanium/tin material in order to induce a high compressive strain. In other cases, a tensile strain may be created, for instance, by providing a silicon/carbon material.

Thereafter, the further processing may be continued, by forming drain and source regions, wherein, in some illustrative process strategies, a portion of the spacer structure 233 may be removed while also the cap material 234 may be removed in order to provide a metal compound for enhancing the conductivity of the electrode structures 230A, 230B, 230C, 230D, while in other cases significant portions of the gate materials may be removed in a very late manufacturing stage, for instance when applying sophisticated replacement gate approaches in which highly conductive electrode metals may be provided, possibly in combination with a high-k dielectric material.

FIG. 2f schematically illustrates the semiconductor device 200 in a further advanced manufacturing stage wherein a configuration may be considered as is also shown in FIG. 2b. That is, a single transistor 240 may be formed on the basis of a gate electrode structure 230 in and above the active region 202A. Furthermore, one or more of the electrode structures 230D may be provided so as to connect to or overlap with the active region 202A in a manufacturing stage in which cavities may be provided for forming therein the strain-inducing semiconductor material 241, as is also previously discussed. Furthermore, drain and source extension regions 242E may be formed in the active region 202A and a spacer structure 235 may be provided in the electrode structures 230, 230D in order to comply with the further processing of the device 200. To this end, in some process strategies, a portion of the sidewall spacer structure 233 (FIG. 2e) may be removed if considered inappropriate for forming the drain and source extension regions 242E, while also the cap material 234 (FIG. 2e) may be removed prior to or after forming the drain and source extension regions 242E. It should be appreciated, however, that any other appropriate process strategy may be applied, depending on the desired device characteristics. Upon removal of a portion of the spacer structure 233 (FIG. 2e) the spacer structure 235 may be formed by well-established deposition and etch techniques, thereby also achieving superior process conditions due to the presence of the structures 230D. In other cases, the previously formed sidewall spacer structure 233 (FIG. 2e) may be preserved and an additional spacer element may be provided so as to form the structure 235 as shown in FIG. 2f. Consequently, the lateral offset for deep drain and source areas still to be formed may be appropriately adjusted on the basis of the spacer structure 235.

FIG. 2g schematically illustrates the semiconductor device 200 in a further advanced manufacturing stage. As shown, drain and source regions 242 may be provided in the active region 202A, possibly in combination with metal silicide regions 243. Similarly, a metal silicide 236 may be formed in the gate electrode structure 230 and also in the electrode structures 230D. The drain and source regions 242 may be formed on the basis of well-established implantation techniques in combination with any anneal processes, followed by appropriate silicidation processes in order to form the materials 243, 236. It should be appreciated that the spacer structure 235 of the electrode structures 230D may result in a certain degree of coverage of the active region 202A, which, however, may not negatively affect the resulting transistor characteristics. Thereafter, the processing may be continued by depositing any appropriate interlayer dielectric material, for instance comprising highly stressed materials, such as silicon nitride, in order to further enhance performance of the transistor 240. Subsequently, contact elements may be formed in the interlayer dielectric material so as to connect to the transistor 240. It should be appreciated that, in other process strategies, materials of the gate electrode structures 230, 230D may be replaced by any appropriate components, for instance after providing a portion of the interlayer dielectric material by means of selective etch techniques and appropriate deposition processes. Also in this case, the electrode structures 230D may provide superior uniformity of the corresponding processes, thereby also contributing to superior uniformity of transistor characteristics.

As a result, the present disclosure provides superior transistor characteristics, for instance in terms of superior threshold voltage, for performance driven transistors having incorporated therein a strain-inducing semiconductor material. To this end, any dummy gate electrode structures may be positioned appropriately at the edge of the active regions so as to provide for substantially similar process conditions at the edge and in the center of the active regions upon depositing the strain-inducing semiconductor material.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a gate electrode structure of a transistor above an active region that is laterally delineated by an isolation region;
forming a dummy gate electrode structure above said isolation region so as to at least connect to an edge portion of said active region, said gate electrode structure and said dummy gate electrode structure being oriented in parallel;
forming a strain-inducing semiconductor alloy in said active region in the presence of said gate electrode structure and said dummy gate electrode structure; and
forming drain and source regions of said transistor in said active region.

2. The method of claim 1, further comprising forming said isolation region in a semiconductor layer so as to adjust the lateral dimensions of said active region for a predefined pitch of said gate electrode structure and said dummy gate electrode structure.

3. The method of claim 1, wherein forming said gate electrode structure and said dummy gate electrode structure comprises forming a sidewall spacer structure on sidewalls of an electrode material, wherein at least a portion of said sidewall spacer structure is formed above said active region.

4. The method of claim 3, wherein forming said strain-inducing semiconductor alloy comprises forming cavities in said active region in the presence of said sidewall spacer structure.

5. The method of claim 4, wherein forming said strain-inducing semiconductor alloy further comprises performing a selective epitaxial growth process and using said sidewall spacer structure as a mask.

6. The method of claim 2, wherein forming said isolation region comprises forming a trench in said semiconductor layer and filling said trench with an insulating material, wherein said trench has inclined sidewall faces.

7. The method of claim 1, wherein said gate electrode structure and said dummy gate electrode structure are formed on the basis of a target gate length of 40 nm or less.

8. The method of claim 1, further comprising forming at least one further gate electrode structure above said active region.

9. The method of claim 8, wherein said gate electrode structure, said at least one further gate electrode structure and said dummy gate electrode structure are formed by using the same target pitch.

10. The method of claim 1, further comprising forming a second dummy gate electrode structure on said isolation region at a second edge portion of said active region, wherein said dummy gate electrode structure and said second dummy gate electrode structure are oriented in parallel to each other.

11. A method of forming a transistor in a semiconductor device, the method comprising:
forming a first gate electrode structure above an active region, said active region being laterally delineated by an isolation region;
forming a second gate electrode structure substantially parallel with said first gate electrode structure above said isolation region so as to connect to an edge region of said active region;
forming cavities in said active region in the presence of said first and second gate electrode structures;
forming a strain-inducing semiconductor alloy in said cavities; and
forming drain and source regions in said active region.

12. The method of claim 11, wherein said first and second gate electrode structures have a gate length of approximately 40 nm or less.

13. The method of claim 12, wherein said second gate electrode structure is formed on said edge region.

14. The method of claim 11, wherein said second gate electrode structure is provided as an electrically non-connected structure.

15. The method of claim 11, further comprising forming a third gate electrode structure above said isolation region so as to cover a second edge region of said active region opposite to said first edge region.

16. The method of claim 11, wherein forming said strain-inducing semiconductor alloy comprises forming a silicon and germanium containing material by selective epitaxial growth.

17. The method of claim 11, wherein forming said strain-inducing semiconductor alloy comprises forming a silicon and carbon containing material by selective epitaxial growth.

18. A semiconductor device, comprising:
a first electrode structure formed above an active region, said active region being laterally delineated by an isolation region;
a second electrode structure formed above said isolation region and connecting to an edge area of said active region, said first and second electrode structures being oriented substantially in parallel; and
a strain-inducing semiconductor alloy formed in said active region, said strain-inducing semiconductor alloy laterally connecting to said edge area.

19. The semiconductor device of claim 18, wherein said first and second electrode structures have a gate length of approximately 40 nm or less.

20. The semiconductor device of claim 20, wherein a fill height of said strain-inducing semiconductor alloy is substantially equal at said first and second electrode structures.
